(19) United States
(12) Patent Application Publication
(10) Pub. No.: US 2018/0171468 A1
(43) Pub. Date: Jun. 21, 2018

(54) METHOD FOR DEPOSTING A FUNCTIONAL MATERIAL ON A SUBSTRATE

(71) Applicant: NCC NANO, LLC, DALLAS, TX (US)

(72) Inventors: ROB JACOB HENDRIKS, EINDHOVEN (NL); PAUL ABEL, DALLAS, TX (US); ERICA COENEN, DALLAS, TX (US)

(73) Assignee: NCC NANO, LLC, DALLAS, TX (US)

(21) Appl. No.: 15/387,297

(22) Filed: Dec. 21, 2016

(51) Int. Cl. C23C 14/58; B05D 1/28

(52) U.S. Cl. CPC C23C 14/5813; B05D 1/28

(57) ABSTRACT

A method for depositing a functional material on a substrate is disclosed. A plate having a first surface and a second surface is provided. A layer of light scattering material is applied onto the first surface of the plate, and a layer of reflective material is applied onto the second surface of the plate. After a group of wells has been formed on the second surface of the plate, a layer of light-absorbing material is applied on the second surface of the plate. Next, the wells are filled with a functional material. The plate is then irradiated with a pulse of light to heat the light-absorbing material in order to generate gas at an interface between the light-absorbing material and the functional material to release the functional material from the wells onto a receiving substrate.

### RELATED PATENT APPLICATION

The present patent application is related to copending application U.S. Ser. No. 15/072,180, filed on Mar. 16, 2016.

### TECHNICAL FIELD

The present invention relates to printing processes in general, and, in particular, to a method for selectively depositing a functional material on a substrate.

### BACKGROUND

A common method for selectively depositing a functional material on a substrate is via printing. The functional material needs to be formulated with other materials before the functional material can be printed on a substrate. Since a formulation is typically formed by dispersing the functional material in a solvent or liquid, the formulation is generally wet. The formulation is often referred to as an ink or paste, depending on the viscosity.

Whether it is ink or paste, a formulation typically includes certain additives intended to make the printing process easier and more reliable, but those additives may also interfere with the properties of the functional material. If the additives within the formulation do not substantially interfere with the intended functions of the functional material to be deposited, the additives can stay; otherwise, the additives must be removed. The removal of additives can be somewhat inconvenient if not impossible.

The present disclosure provides an improved method for printing a functional material on a substrate.

### SUMMARY OF THE INVENTION

In accordance with a preferred embodiment of the present invention, a plate having a first surface and a second surface is provided. A layer of light scattering material is applied onto the first surface of the plate, and a layer of reflective material is applied onto the second surface of the plate. After a group of wells has been formed on the second surface of the plate, a layer of light-absorbing material is applied on the surface of the wells. Next, the wells are filled with a functional material. The plate is then irradiated with a pulse of light to heat the light-absorbing material in order to generate gas at an interface between the light-absorbing material and the functional material to release the functional material from the wells onto a receiving substrate.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIGS. 1A-1B depict a laser induced forward transfer process;

FIG. 2 is a process flow diagram of a method for depositing a functional material on a substrate; and

FIGS. 3A-3E graphically illustrate the method of FIG. 2.

### DETAILED DESCRIPTION OF A PREFERRED EMBODIMENT

Ideally, instead of printing a functional material on a substrate, selectively depositing a pure functional material on a substrate is most preferable, but it is almost never done. To a certain extent, printing a near pure functional material, such as pastes with high solids content, can be performed by using a Laser Induced Forward Transfer (LIFT) process.

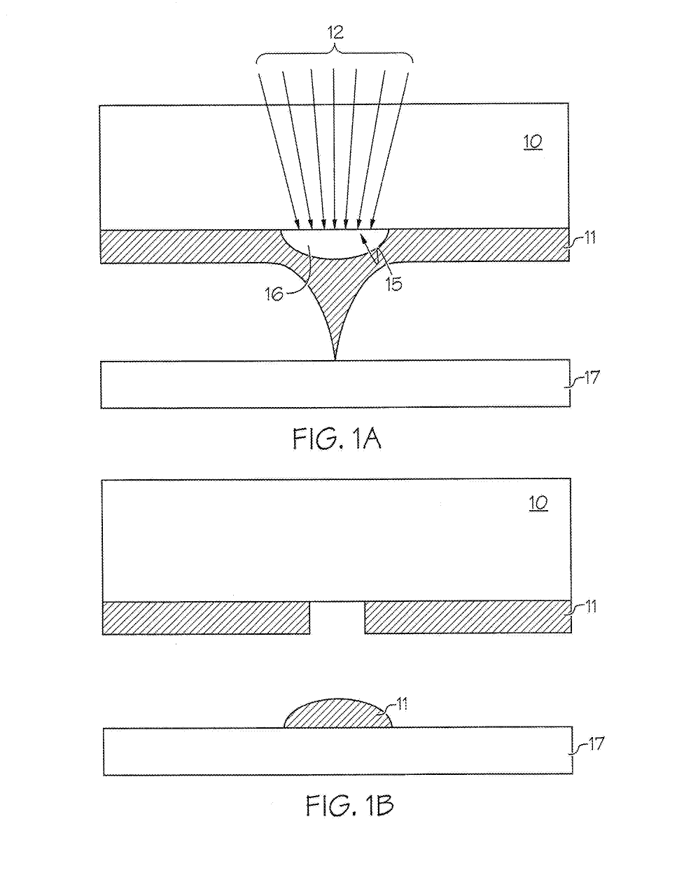

Referring now to the drawings and in particular to FIGS. 1A-1B, there is depicted the LIFT process. Initially, a functional material 11 is placed on one side of a donor substrate 10 that is at least partially optically transparent. A laser beam 12 is then placed on the other side (opposite from the side on which functional material 11 is placed) of donor substrate 10, and laser beam 12 is focused to a point near an interface 15 between functional material 11 and donor substrate 10, as shown in FIG. 1A. A gas 16 is subsequently generated at interface 15, and gas 16 propels a small portion of functional material 11 onto a receiver substrate 17, as shown in FIG. 1B.

There are several disadvantages to the LIFT process. First, the thicker the deposition, the lower the resolution of a final print. Second, since only a single spot of functional material can be transferred at a time, the LIFT process can only be performed in a serial manner. Third, there is a considerable amount of waste in the LIFT process because only a relatively small portion of the functional material on the donor substrate is utilized. Finally, and perhaps the biggest disadvantages of the LIFT process is that there are specific requirements on the dynamic characteristics of the functional material to be printed. In other words, the LIFT process is not suitable for all types of functional materials, and the printing parameters need to be fine-tuned for each type of functional materials. The margin of error for the tuning is relatively small because the homogeneity of the layer thickness and the viscosity will vary across the entire donor substrate.

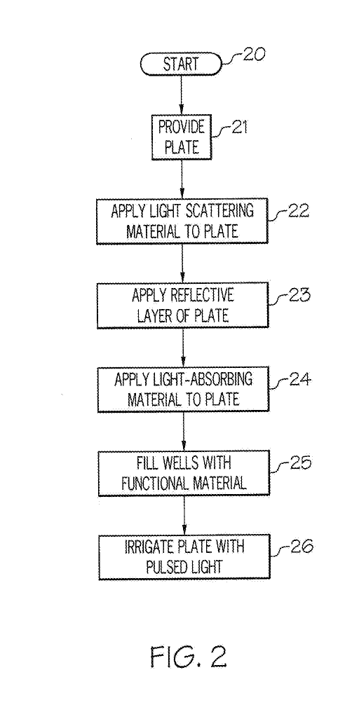

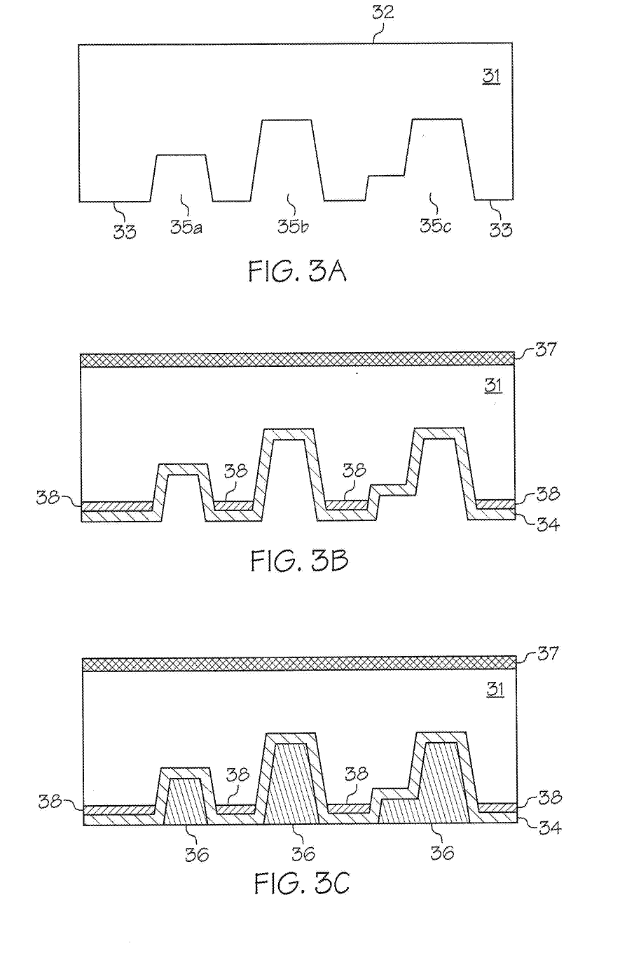

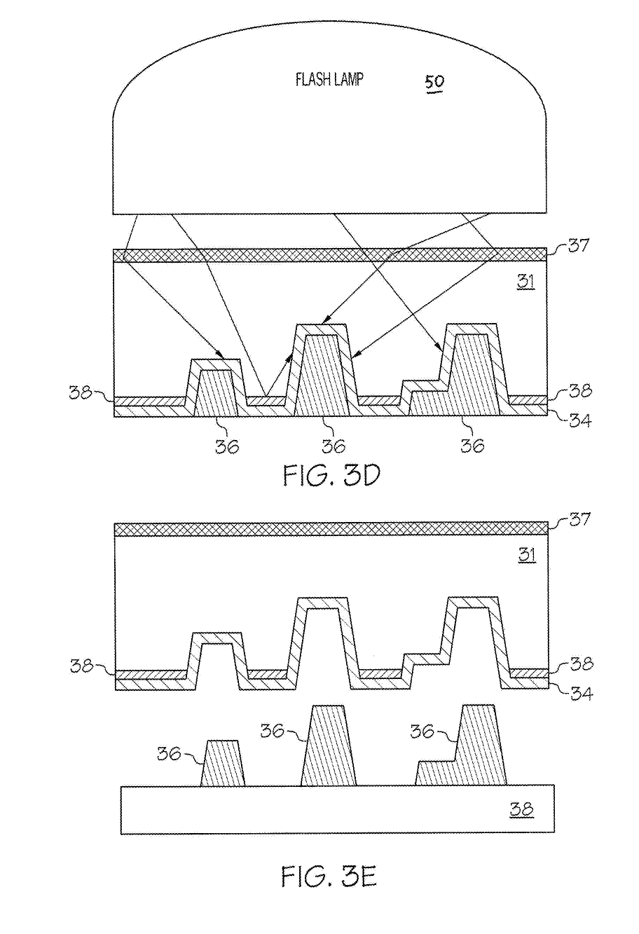

With reference now to FIG. 2, there is illustrated a method for depositing a functional material on a substrate, in accordance with a preferred embodiment of the preset invention. Starting at block 20, an optically transparent plate is provided, as shown in block 21. The optically transparent plate is preferably made of quartz. The optically transparent plate, which is depicted as a plate 31 in FIG. 3A, includes a first surface 32 and a second surface 33. First surface 32 is preferably flat, but it can also be curved. Second surface 33 is preferably dimpled with multiple wells 35a, 35b and 35c. The depth of each of wells 35a-35c is preferably between 10 nm to 1,000 μm, and the exact depth of a well depends on specific application. Wells 35a-35c is preferably formed by laser femptosecond laser drilling, but they can also be formed by etching. Although only three wells 35a-35c are shown in FIG. 3A, it is understood by those skilled in the art that second surface 33 may have more than three wells.

A light scattering material layer 37 is applied to first surface 32 of plate 31, as depicted in block 22 and in FIG. 3B. Light scattering material layer 37 can also be applied at the later stage of this method. Plate 31 has an index of refraction greater than 1, and incident light impinging upon plate 31 has a tendency to bend towards the normal angle drawn from the plane of plate 31. The bending of the incident radiation by plate 31 makes the irradiation of the absorptive layer less uniform, and by applying light scattering layer 37 on first surface 32 of plate 31, such effect can be mitigated. Another light scattering material layer may also be placed on second surface 32 of plate 31 before a reflective layer is deposited. Such a layer additionally increases the uniformity of the light impinging on an absorptive layer. Light scattering material layer may be made of a variety of materials such as porous materials, microlens arrays, patterned structures, and metamaterials. It may also be generated by roughening incident surface 32.

After applying a reflective material layer 38 on second surface 33 of plate 31, as shown in block 23, reflective material layer 38 can be selectively etched away, as shown in FIG. 3B. When having a high contrast ratio between reflective material layer 38 and a light-absorbing material layer, it is possible to only reach the phase change temperature of the solvent in the functional material within wells 35a-35c and not on second surface 33 of plate 31. As filling wells 35a-35c might not be a 100% clean process, reflective material layer 38 prevents that any functional material on second surface 33 of plate 31 from not reaching the phase change temperature of the solvent in the functional material. A possible material for reflective material layer 38 is aluminum.

Next, a light-absorbing material layer 34 is applied to second surface 33 of plate 31, as depicted in block 24 and in FIG. 3B. Light-absorbing material layer 34 needs to be thermally stable (i.e., thermal shock resistant). Preferably, light-absorbing material layer 34 is made of tungsten.

Wells 35a-35c of plate 31 are then filled with a functional material 36, as shown in block 25 and in FIG. 3C. Functional material 36 can be in the form of an ink or paste. A squeegee or doctor blade can be utilized to fill wells 35a-35c with functional material 36. After wells 35a-35c have been filled with functional material 36, plate 31 is irradiated by a pulsed light, preferably on first surface 32, as depicted in block 26 and in FIG. 3D. Preferably, the pulsed light is generated by a flashlamp 37.

When the pulsed light hits plate 31, a portion of the photons are converted into phonons that subsequently heat up light-absorbing material layer 34. While light-absorbing material layer 34 is being heated, functional material 36 within wells 35a-35c will be heated through thermal diffusion (primarily conduction). When the boiling or sublimation phase change temperature of one or multiple components of functional material 36 has been reached at an interface between light-absorbing material layer 34 and functional material 36, gas is generated at the interface between light-absorbing material layer 34 and functional material 36. The gas then expels functional material 36 from plate 31 to a receiving substrate 38, as shown in FIG. 3E. The transfer of functional material 36 may also be assisted by gravity.

The above-mentioned steps may be repeated by re-applying the functional material to wells 35a-35c of plate 31 followed by another exposure of pulsed light from flashlamp 37 to expel the functional material from wells 35a-35c onto receiving substrate 37.

In addition to well depths, the shape of wells 35a-35c can be adjusted to help controlling the expulsion of functional material 36, and to improve the filling of functional material 36.

It is important to supply a uniform application of heat onto light-absorbing material layer 34 in order to make sure functional material 36 is heated in a consistent manner such that functional material 36 in wells 35a-35c loses adhesion to plate 31 at the same time. If not, functional material 36 will be ejected in various directions Furthermore, if functional material 36 were to be inconsistently heated, functional material 36 may have inconsistent properties after expulsion. An ejection of functional material 36 from wells 35a-35c should undergo almost no shear stress.

A uniform application of heat on light-absorbing material layer 34 is preferably achieved by using a non-collimated light source with a spatially uniform beam profile. As each of wells 35a-35c has a curved surface, the radiant power at the surface of wells 35a-35c is proportional to the cosine of the incident angle of the light impinging upon them. Thus, a collimated beam of light would not produce a uniform heating profile unless the spatial intensity of the beam varied as the 1/cosine of the incident angle of the light over each of wells 35a-35c. This problem does not exist when the pulsed light is non-collimated.

An example of a non-collimated light source that can have a spatially uniform beam intensity is flashlamp 37 mentioned above. Another example of a non-collimated source is a laser coupled to a waveguide. The laser alone is a coherent source, but after passing through a waveguide, a laser beam from the laser loses its coherency, and therefore becomes non-collimated. When the intensity of the laser beam is spatially uniform, a uniform heating of light-absorbing material layer 34 can be achieved.

In order to use a flashlamp, such as flashlamp 37, as a light source, the flashlamp preferably has a beam uniformity of less than 5% and more preferably less than 2%, and the intensity is preferably greater than 5 KW/cm², and more preferably, greater than 10 KW/cm². In addition, the pulse of light is preferably be less than 1 ms, and more preferably less than 0.2 ms. The higher the thermal diffusivity of plate 30 and light-absorbing material layer 34, the higher the intensity and the shorter the pulse length are required. The uniformity of the intensity of the beam is preferably less than 5%, and more preferably less than 2%.

If an under-powered flashlamp were to be used, then functional material 36 would not be properly released from wells 35a-35c. More specifically, if a pulse of light is with too low of an intensity is used, a longer time duration is required to reach the is temperature required for ejecting functional material 36 from plate 31. This means that due to thermal diffusion, more of functional material 36 will be heated before it is eventually is ejected. This is undesirable for many type of functional materials. Thus, for smaller wells, a higher amount of functional material 36 will be affected.

Since the source of light is non-collimated, it is possible to utilize the present invention to print functional material onto a non-planar substrate, e.g., a three-dimensional structure. In this case, the surface having the wells may be discontinuous or curved to match the surface of the receiving substrate. This may have useful applications such as printing an antenna onto a curved surface either concave or convex or even over discontinuous surfaces.

The following are additional types of layers that allow the method of the present invention to be even more flexible and more advantageous.

### Thermal Buffer Layer

A thermal buffer layer can be applied on second surface 33 of plate 31 before the application of light-absorbing material layer 34 on second surface 33 of plate 31. The thermal buffer layer exhibits a low thermal conductivity. When the thermal buffer layer has a lower thermal conductivity than plate 31, it retards the heat pulse from light-absorbing material layer 34 on the flat part of plate 31.

An example of a thermal buffer layer is a polymer such is polyimide. Polyimide has a thermal conductivity of about 0.5 W/m-K, which is a factor of approximately 2.5 lower than that of quartz. The thickness of the thermal buffer layer is preferably less than 10 micron.

### Release Layer

Before an application of functional material 36, a thin layer of material having a relatively low boiling point may be applied to facilitate the release of functional material 36 from plate 31. The application can be performed by a number of deposition technologies such as roll coating, vapor deposition, misting, etc. Preferably, the release layer has a phase change temperature equal to or lower than any of the solvents or components in functional material 36. A possible material for the release layer is polypropylene carbonate).

The release layer may also be absorptive of light. In this case, it can serve as the absorptive layer as well. It must be re-applied for each printing step.

### Porous Release Layer

The release mechanism of functional material 36 can be improved by applying a thin micro- or nano-structural layer within wells 35a-35c, between functional material 36 and light-absorbing material layer 34. The release structure needs to be able to contain a solvent, so it has to have pores. Depending on the particle size of functional material 36, the pore size can be either in the micrometer- or nanometer-range. The pores in the release structure are filled with a low boiling point solvent before application of functional material 36. Typically, a low boiling point solvent also has a low phase change temperature, meaning that functional material 36 can be printed with a lower energy light pulse. Alternatively, the solvent from functional material 36 can preferentially go into the pores when it is applied. In both cases, the gas generation within the release structure is less dependent on the properties of functional material 36. This should lead to a more homogeneous process. Also, thermal damage to functional material 36 can be further prevented, as it is not heated in a direct manner.

This may be important when printing biological materials that are thermally fragile. Even without the release layer, this is a “cold” printing process as there is little time to transfer much heat. Functional material 36 will always heat up until it reaches the phase change temperature. However, it is typically less than 1 μm of material that is significantly heated. However, with the release layer, the peak temperature seen by functional material 36 is reduced further.

An alternative to a porous release layer structure for the purpose of helping to eject the functional material is the application of a low surface tension layer between light-absorbing material layer 34 and functional material 36 to enhance the release of functional material 36 as well as enhance the cleanability of the surface after printing and before the subsequent application of more functional material 36. The low surface tension layer may also be selectively applied within a well so as to encourage deposition of functional material 36 onto desired portions of wells 35a-35c.

Light-absorbing material layer 34 may be selectively coated with the low surface tension layer to functional material 36 to aid in releasing functional material 36 from wells 35a-35c.

As has been described, the present invention provides a method for depositing a functional layer on a substrate. Unlike the LIFT process, the method of the present invention requires no scanning. Unlike the LIFT process, nearly 100% of the functional material is utilized by the method of the present invention. Unlike the LIFT process, there is no by-product or waste such as unused paste or transfer tape with the method of the present invention.

A further advantage of the present invention is that the shape and profile of the wells can be varied to achieve various effects. More interestingly, the depth of the wells can be varied across the plate as well. Since the depth of the well is related to the amount of material that is being dispensed, the present invention allows the simultaneous deposition of material of different thicknesses. This has some very practical implications. For example, in circuit boards, it is common for electrical traces to be thin and contact pads to be thick. Normally, this would require two separate printing, and the second of those printing needs to be registered to the first, With this invention, the deposition of a thin and thick trace can be performed in a single step saving time and increasing the quality of the print as no registration is needed.

While the invention has been particularly shown and described with reference to a preferred embodiment, it will be understood by those skilled in the art that various changes in form and detail may be made therein without departing from the spirit and scope of the invention.

1. A method for depositing a functional material on a substrate, said method comprising:
providing a plate having a first surface and a second surface;
removing materials from said second surface to form a plurality of wells within said second surface, wherein said plurality of wells have different depths;
depositing a light scattering material layer on said first surface:
depositing a light absorbing material layer on said second surface including said plurality of wells:
filling said plurality of wells with a functional material; and
irradiating said plate with pulsed light to heat said light-absorbing material in order to generate gas at an interface between said light-absorbing material and said functional material to release said functional material from said plurality of wells onto a receiving substrate.

2. The method of claim 1, wherein said plate is optically transparent.

3. The method of claim 1, wherein depths of said plurality of wells range from 10 nm to 1,000 μm.

4. The method of claim 1, wherein said light-absorbing material is tungsten.

5. The method of claim 1, wherein said removing includes laser drilling.

6. The method of claim 1, wherein said removing includes etching.

7. The method of claim 1, wherein said method further includes depositing a light scattering material layer on said second surface of said plate.

8. The method of claim 1, wherein said method further includes roughening said first surface.

9. The method of claim 1, wherein said second surface is non-planar.

10. The method of claim 1, wherein said receiving substrate is non-planar.

11. A method for depositing a functional material on a substrate, said method comprising:
providing a plate having a first surface and a second surface:
removing materials from said second surface to form a plurality of wells within said second surface, wherein said plurality of wells have different depths;
coating said second surface of said plate except said plurality of wells with a light reflecting material layer;
depositing a light absorbing material layer directly on said light reflecting material layer and inside said plurality of wells;
filling, said plurality of wells with a functional material; and
irradiating said plate with pulsed light to heat said light-absorbing material in order to generate gas at an interface between said light-absorbing material and said functional material to release said functional material from said plurality of wells onto a receiving substrate.

12. The method of claim 11, wherein said plate is optically transparent.

13. The method of claim 11, wherein depths of said plurality of wells range from 10 nm to 1,000 μm.

14. The method of claim 11, wherein said light-absorbing material is tungsten.

15. The method of claim 1, wherein said removing includes laser drilling.

16. The method of claim 1, wherein said removing includes etching.

17. The method of claim 11, wherein said method further includes depositing a light scattering material layer on said second surfaces of said plate before said deposition of said reflective layer.

18. The method of claim 11, wherein said second surface is non-planar.

19. The method of claim 11, wherein said receiving substrate is non-planar.
